(19) United States
(12) Patent Application Publication
(10) Pub. No.: US 2006/0272938 A1
(43) Pub. Date: Dec. 7, 2006

(54) METHOD OF MANUFACTURING A LIQUID CRYSTAL ALIGNMENT FILM UTILIZING LONG-THROW SPUTTERING

(76) Inventors: Ta-Shuang Kuan, Hsin-Chu Hsien (TW); Yi-Ming Chang, Hsin-Chu City (TW); Chia-Te Lin, Chia-Yi Hsien (TW); Chia-Tsung Chan, Tao-Yuan Hsien (TW)

Correspondence Address: NORTH AMERICA INTELLECTUAL PROPERTY CORPORATION, P.O. BOX 506, MERRIFIELD, VA, 22116, US

(21) Appl. No.: 10/908,916

(22) Filed: Jun. 1, 2005

(51) Int. Cl. C23C 14/00

(52) U.S. Cl. 204/192.15

(57) ABSTRACT

The present invention provides a method of manufacturing an LC alignment film utilizing long-throw sputtering. The method includes putting a substrate on a substrate carrier in a chamber, utilizing high-density plasma to bombard a target over the substrate to produce sputtering species, and providing a bias voltage in the chamber. Nearly vertical directional sputtering species are deposited on the surface of the substrate to form an LC alignment film. The distance between the target and the substrate is more than 20 cm.

### BACKGROUND OF INVENTION

1. Field of the Invention

The invention relates to manufacturing a liquid crystal (LC) alignment film, and more particularly, to utilizing long-throw sputtering or a collimator to manufacture a liquid crystal alignment film.

2. Description of the Prior Art

Liquid Crystal (LC) displays are widely used in various applications. Generally, the image quality of small-sized LC displays is close to the image quality of conventional CRT displays. However, in some large-sized, high-density LC applications, problems including viewing angle, contrast, display uniformity, response time, etc. are still to be overcome. In the manufacture of LCD devices, as known in the art, the alignment of LC molecules sandwiched between transparent electrodes formed on opposed substrate plates is critical. To obtain better contrast, the orientation of the LC molecules must be uniformly controlled.

The alignment types of the LC molecules are generally divided into three categories: (1) homogeneous alignment, (2) homeotropic or vertical alignment, and (3) tilted homeotropic alignment. The latter is the most applicable one in industry. The LC molecules in contact with the alignment layer are arranged at a pre-tilt angle with respect to the alignment surface. As known in the art, the pre-tilt angle is one of the critical parameters of a LCD device and is determined by physical forces such as hydrogen bond, Van der Waals force, and mechanical forces such as grooves formed on an alignment layer and materials chosen for the alignment layer.

The industry-wide method for producing an alignment layer is through the mechanical rubbing of a polyimide surface. This method requires a physical contact between a rubbing cloth and the polyimide surface. The rubbing process realigns the surface of the polyimide, which then acts as an alignment template for the orientation of the liquid crystal molecules in the preferred pre-tilt direction.

This approach has several disadvantages. For example, because the rubbing method is a contact technique, debris can be generated during the rubbing process resulting in a low process yield. Moreover, additional cleaning steps are generally required to remove the debris. In addition, as the roller or brush rubs the surface of the display, electrostatic charges can build up which may discharge through the thin film transistors (TFT) resulting in a lowering of the process yield. Furthermore, the PI organic film cannot easily pass the reliability test that will influence the quality of TFT. Additionally, the rubbing process requires a relatively soft layer in order to modify the surface in a desired orientation. Thus, choice of materials that are suitable for use in the rubbing process is limited.

### SUMMARY OF INVENTION

It is therefore a primary objective of the claimed invention to provide a method of manufacturing a uniform LC alignment film to solve the above-mentioned problem.

According to the claimed invention, the method includes putting a substrate on a substrate carrier in a chamber, utilizing high-density plasma to bombard a target over the substrate to produce sputtering species, and providing a bias voltage in the chamber. Then, nearly vertical directional sputtering species are deposited on the surface of the substrate to form an LC alignment film. The distance between the target and the substrate is more than 20 cm.

Alternatively, according to the claimed invention, the method includes putting a substrate on a substrate carrier in a chamber, utilizing high-density plasma to bombard a target over the substrate to produce sputtering species, and providing a collimator between the target and the substrate. Then the sputtering species is accorded a specific directional deposit on the surface of the substrate to form an LC alignment film.

The claimed invention uses inorganic alignment materials to form a target, and utilizes sputtering to manufacture a LC alignment film. Not only does the claimed invention eliminate the problems of the alignment film passing the reliability test, the trace of rubbing cloth, and the agreement of alignment film, but it also improves the breakthrough and quality of the alignment film to reduce the cost.

These and other objectives of the claimed invention will no doubt become obvious to those of ordinary skill in the art after reading the following detailed description of the preferred embodiment that is illustrated in the various figures and drawings.

These and other objectives of the present invention will no doubt become obvious to those of ordinary skill in the art after reading the following detailed description of the preferred embodiment that is illustrated in the various figures and drawings.

### BRIEF DESCRIPTION OF DRAWINGS

FIG. 1 is a schematic diagram of manufacturing an LC alignment film utilizing the general sputtering.

FIG. 2 and FIG. 3 are schematic diagrams of manufacturing an LC alignment film utilizing long-throw sputtering according to the present invention.

FIG. 4 and FIG. 5 are schematic diagrams of manufacturing a LC alignment film utilizing a collimator according to the present invention.

### DETAILED DESCRIPTION

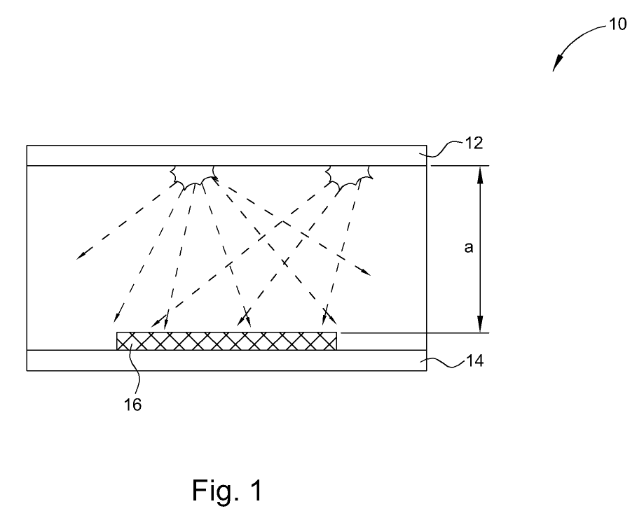

Please refer to FIG. 1 that is a schematic diagram of manufacturing a LC alignment film utilizing the general sputtering technique. As shown in FIG. 1, a chamber 10 includes a target 12 and a substrate carrier 14, and a substrate 16 put on the substrate carrier 14. Between the substrate 16 and the target 12 is a distance “a”. Then a sputtering process is performed for manufacturing an LC alignment film. Dotted line arrows shown in FIG. 1 illustrate the directions and distances of the sputtering ions. However, the distance “a” between the target 12 and substrate 16 is about 10 cm so that an angle of the sputtering species depositing on the substrate 16. The substrate 16 is too broad to permit various orientational grooves on the LC alignment of the substrate 16 and influences the angle of the LC molecules and the surface of the alignment film 16, and reduces the quality and yield of the LC alignment film.

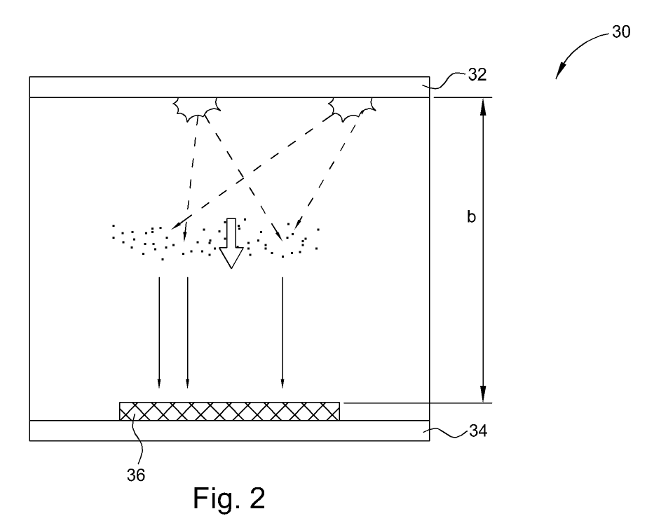

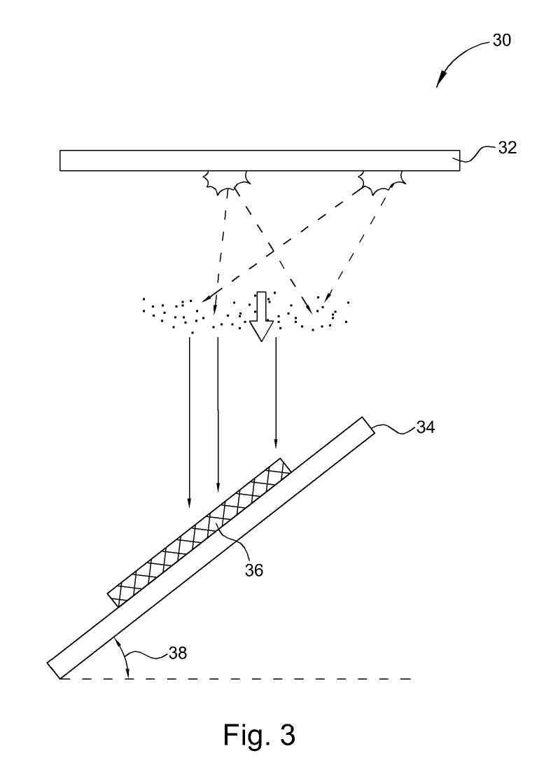

Please refer to FIG. 2 and FIG. 3 that are schematic diagrams of manufacturing an LC alignment film utilizing long-throw sputtering according to the present invention. As shown in FIG. 2, the present invention provides a chamber 30 including a target 32, a substrate carrier 34, and a substrate 36 is put on the substrate carrier 34 in the chamber 30. Between the substrate 36 and the target 32 is a distant “b”. Then utilizing high-density plasma to bombard the target 32 in the chamber 30, the target 32 generates sputtering species (as the dotted arrows shown in FIG. 2). For the sputtering species deposited on the surface of the substrate 36 having a predetermined orientation, the distance “b” between the substrate 36 and the target 32 is controlled to reach the standard of long-throw sputtering. For example, the distance “b” is at least more than 20 cm, but a preferred distance B is 25˜90 cm. Furthermore, the sputtering species can react with the high-density plasma in the chamber 30 to producing ionization due to a bias voltage (not shown) in the chamber 30 being provided. For instance, the upside and underside of the chamber 30 provides a direct current voltage to deposit the nearly vertical directional ionizing sputtering species on the surface of the substrate 36 (as the solid arrow shown in FIG. 2) to form an LC alignment film. As a result, the angle of the LC alignment and the LC molecules can be controlled to form a uniform alignment film.

As shown in FIG. 3, nearly vertical directional sputtering species is deposited on the substrate 36 according to present invention so that the kind of the LC molecules and the needed pre-tilt angle of the LC molecules and alignment film can be regarded to adjust the pre-tilt angle of the LC. According to the embodiment of the present invention, the substrate 36 and the substrate carrier 34 can tilt at an angle, and then proceeding with the sputtering process, the sputtering species is deposited on the surface of the substrate 36 to form the LC alignment film. In addition, the surface of the LC alignment film of the substrate 36 has an LC pre-tilt angle. The tilt angle 38 of the substrate 36 is about 20˜70 degree. Furthermore, the method further includes providing a collimator (not shown) between the substrate 36 and the target 32 for adjusting the surface angle of sputtering species depositing on the substrate, while the sputtering species deposits the LC alignment film.

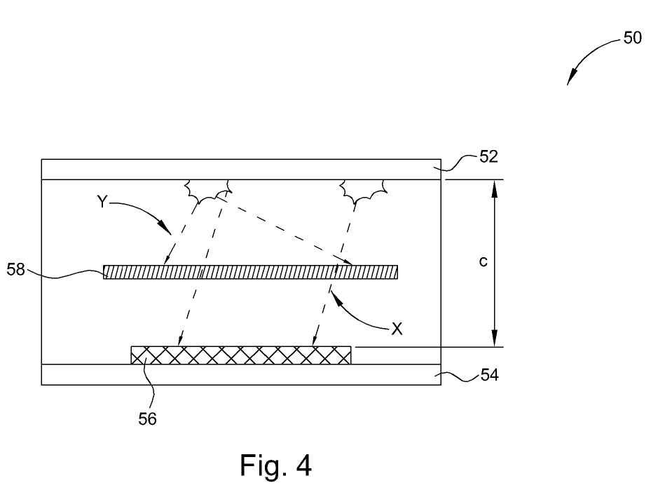

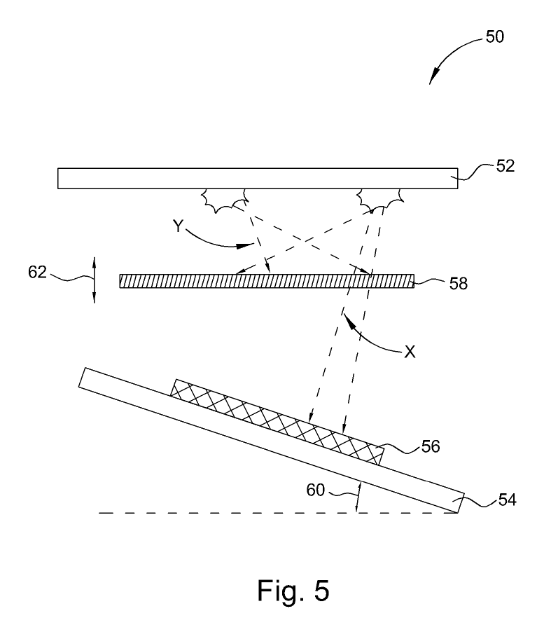

Please refer to FIG. 4 and FIG. 5, which are schematic diagrams of manufacturing an LC alignment film utilizing a collimator according to the present invention. As shown in FIG. 4, the present invention provides a chamber 50 including a target 52, a substrate carrier 54, and a substrate 56 is put on the substrate carrier 54 in the chamber 50. Between the substrate 56 and the target 52 is a distant “c”. Moreover, a collimator 58 is put between the substrate 56 and the target 52. Then utilizing high-density plasma to bombard the target 52 in the chamber 50, the target 32 generates sputtering species, and the sputtering species passes through the collimator 58 and deposits on the substrate 56 to form the LC alignment film. Only nearly vertical (meaning perpendicular to the plane of the collimator 58) sputtering species is allowed to pass through the collimator 58 (as dotted lines X shown in FIG. 4), and other angled sputtering species is sieved out by the collimator 58 (as dotted lines Y shown in FIG. 4). Therefore, the sputtering species can be controlled to obey the tilt angle of the collimator 56 to deposit and form a uniform LC alignment film.

As shown in FIG. 5, the kind of LC molecules and the needed pre-tilt angle of the LC molecules and alignment film can be regarded to adjust the tilt angle of the substrate 56 or the location of the collimator 58. Therefore, the sputtering species accorded the needed angle are deposited on the surface of the substrate 56, and the surface of LC alignment film of the substrate 56 has an LC pre-tilt angle. In addition, the pre-tilt angle 60 of the substrate 56 is about 20˜70 degree, and the distances of the collimator 58 between the target 52 and the substrate 56 can be adjusted according to the needed pre-tilt angle of the LC alignment film (as twin arrows 62 shown in FIG. 5).

As above-mentioned, the pressures in the chambers 30, 50 are about 0.03˜0.1 mtorr, the distance “b” between the target 32 and the substrate 36 is about 25˜90 cm, the distance “c” between the target 52 and the substrate 56 is about 20˜70 cm, and the surface area of the targets 32, 52 is larger than that of the substrates 36,56. In addition, the LC alignment film (formed by the target 32, 52) includes a diamond-like carbon thin film or a silicon oxide thin film, forming an inorganic material layer or a high-pass non-conducting material layer, such as SiO₂, SiOₓ, or any dielectric material.

It is to be noted that the collimator 58 includes a plurality of channels, and the aspect ratio of each channel is 2:1. In addition, each channel is similar to a hexagonal tube so that the collimator 58 is similar to a beehive. Furthermore, the collimator 58 can sieve out large angled sputtering species, and allows small angled sputtering species to pass through the channels to deposit on the surface of the substrate 56 and form the LC alignment film.

To sum up, the present invention utilizes long-throw sputtering or a collimator to manufacture an LC alignment film encompasses at least the following advantages.

(1) The present invention utilizing long-throw sputtering to manufacture an LC alignment film can form nearly vertical sputtering species deposits on a substrate, which can effectively avoid many unwanted pre-tilt angles on the LC alignment film and improve the quality of the LC alignment film.

(2) The present invention utilizing a collimator to manufacture an LC alignment film can form a uniform LC alignment film by changing the location of the collimator to sieve out the sputtering species or allowing the sputtering species to pass through the collimator.

(3) The present invention utilizing long-throw sputtering or a collimator to manufacture an LC alignment film can utilize the tilt angle of the substrate to control the pre-tilt angle of the LC molecules and LC alignment film, which can effectively improve the quality and yield to reduce cost.

(4) The present invention utilizing long-throw sputtering or a collimator to manufacture an LC alignment film adopts inorganic materials to manufacture the LC alignment film to solve the problem of the PI film passing the reliability test.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A method of manufacturing a Liquid Crystal (LC) alignment film utilizing long-throw sputtering, the method comprising:
putting a substrate on a substrate carrier in a chamber;
utilizing high-density plasma to bombard a target over the substrate to produce sputtering species; and
providing a bias voltage in the chamber, a nearly vertical directional sputtering species depositing on the surface of the substrate to form the LC alignment film;
wherein a distance between the target and the substrate is more than 20 cm.

2. The method of claim 1, wherein the LC alignment film is an inorganic material layer.

3. The method of claim 1, wherein the LC alignment film is a high-pass non-conducting material layer.

4. The method of claim 1, wherein the LC alignment film comprises a diamond-like carbon thin film.

5. The method of claim 1, wherein the LC alignment film comprises a silicon oxide thin film.

6. The method of claim 1 further comprising providing the substrate with a tilt angle for providing a LC pre-tilt angle on the LC alignment film, while the sputtering species deposits the LC alignment film.

7. The method of claim 6, wherein the pre-tilt angle of the substrate is about 20˜70 degree.

8. The method of claim 1 further comprising providing a collimator between the substrate and the target for adjusting the surface angle of sputtering species depositing on the substrate, while the sputtering species deposits the LC alignment film.

9. The method of claim 8, wherein the collimator comprises a plurality of channels and the aspect ratio of each channel is 2:1.

10. The method of claim 1, wherein the surface area of the target is larger than the surface area of the substrate.

11. The method of claim 1, wherein the pressure in chamber is about 0.03˜0.1 mtorr.

12. The method of claim 1 wherein the distance between the target and the surface of the substrate is about 25˜90 cm.

13. A method of manufacturing Liquid Crystal (LC) alignment film, the method comprising:
putting a substrate on a substrate carrier in a chamber;
utilizing high-density plasma to bombard a target over the substrate to produce sputtering species; and
providing a collimator between the target and the substrate, the sputtering species accorded a specific direction to deposit on the surface of the substrate to form the LC alignment film .

14. The method of claim 13, wherein the LC alignment film is an inorganic material layer.

15. The method of claim 13, wherein the LC alignment film is a high-pass non-conducting material layer.

16. The method of claim 13, wherein the LC alignment film comprises a diamond-like carbon thin film.

17. The method of claim 13, wherein the LC alignment film comprises a silicon oxide thin film.

18. The method of claim 13 further comprising providing the substrate with a tilt angle for providing a LC pre-tilt angle on the LC alignment film, while the sputtering species deposits the LC alignment film.

19. The method of claim 13, wherein the pre-tilt angle of the substrate is about 20˜70 degree.

20. The method of claim 13, wherein the collimator comprises a plurality of channels and the aspect ratio of each channel is 2:1.

21. The method of claim 13, wherein the surface area of the target is larger than the surface area of the substrate.

22. The method of claim 13, wherein the pressure in chamber is about 0.03˜0.1 mtorr.

23. The method of claim 13, wherein the distance between the target and the surface of the substrate is about 20˜70 cm.
